(19) United States
(12) Patent Application Publication
(10) Pub. No.: US 2026/0372152 A1
(43) Pub. Date: Nov. 19, 2026

(54) INTEGRATED ELECTRONIC DEVICE

(71) Applicant: STMicroelectronics International N.V., Geneva (CH)

(72) Inventors: Jean-Christophe GIRAUDIN, Crolles (FR); Thomas OHEIX, Crolles (FR)

(21) Appl. No.: 19/677,920

(22) Filed: May 14, 2026

(30) Foreign Application Priority Data
May 15, 2025 (FR) 2505197

(51) Int. Cl. H10W 72/00; H10W 72/90

(52) U.S. Cl. CPC H10W 72/01935; H10W 72/01971; H10W 72/9232; H10W 72/934; H10W 72/952

(57) ABSTRACT

The present description concerns a method of manufacturing an electronic device comprising successive steps: a) forming a structure comprising a metal pad coated with an insulating stack, the insulating stack comprising an opening facing the metal pad; b) depositing a conductive seed layer in the opening on top of and in contact with an upper side of the metal pad, the conductive seed layer further extending on top of and in contact with the flanks of the insulating stack and on top of and in contact with an upper side of the insulating stack at the periphery of the opening; and c) forming, by an electroless deposition method, a conductive element on top of and in contact with the entire upper side of the conductive seed layer as well as on top of and in contact with the flanks of the conductive seed layer at the periphery of the opening.

### CROSS-REFERENCE TO RELATED APPLICATIONS

This application is based on and claims priority benefit of French patent application number FR2505197, filed on May 15, 2025, entitled “Dispositif électronique intégré,” the contents of which is incorporated herein by reference in its entirety.

### FIELD OF INVENTION

The present disclosure generally concerns integrated electronic devices and more particularly integrated electronic devices comprising metallizations on a contact pad.

### BACKGROUND

An integrated electronic device conventionally comprises a substrate, for example made of a semiconductor material, inside and/or on top of which electronic components are formed. The substrate is coated with a stack of metal and insulating layers, also called interconnection stack or interconnection network, in which conductive interconnection elements are formed. The interconnection stack may comprise metal pads, also known as contact pads, intended to be connected to an external device. In some technologies, the metal contact pads are coated with an over-pad metallization also called OPM aiming at preventing risks of oxidation of the contact pad.

It would be desirable to at least partially overcome some of the disadvantages of known embodiments of such devices.

### SUMMARY

For this purpose, an embodiment provides a method of manufacturing an electronic device comprising the following successive steps: a) forming a structure comprising a metal pad coated with an insulating stack, the insulating stack comprising an opening facing the metal pad; b) depositing a conductive seed layer in the opening on top of and in contact with an upper side of the metal pad, the conductive seed layer further extending on top of and in contact with the flanks of the insulating stack and on top of and in contact with an upper side of the insulating stack at the periphery of the opening; and c) forming, by an electroless deposition method, a conductive element on top of and in contact with the entire upper side of the conductive seed layer as well as on top of and in contact with the flanks of the conductive seed layer at the periphery of the opening.

According to an embodiment, the conductive element is made of nickel.

According to an embodiment, the conductive seed layer is made of nickel, titanium, titanium nitride, tantalum, tantalum nitride, or an alloy of titanium and copper.

According to an embodiment, during step b), the conductive seed layer is deposited with a thickness in the range from 50 nm to 500 nm.

According to an embodiment, during step b), the conductive seed layer is deposited by a vapor deposition method.

According to an embodiment, during step b), the conductive seed layer is deposited by a physical vapor deposition method.

According to an embodiment, during step b), the conductive seed layer is deposited by a chemical vapor deposition method.

According to an embodiment, the method comprises, between steps a) and b), a step of plasma treatment of the surface of the metal pad.

According to an embodiment, the method comprises, after step c), a step of deposition of another conductive layer on top of and in contact with an upper side of the metal element.

According to an embodiment, the other conductive layer is made of palladium.

According to an embodiment, the other conductive layer has a thickness in the range from 100 nm to 500 nm.

Another embodiment provides an electronic device comprising: a metal pad coated by an insulating stack, the insulating stack comprising an opening facing the metal pad; a conductive seed layer in the opening on top of and in contact with an upper side of the metal pad, the conductive seed layer further extending on top of and in contact with the flanks of the insulating stack and on top of and in contact with an upper side of the insulating stack at the periphery of the opening; and a conductive element on top of and in contact with the entire upper side of the conductive seed layer as well as on top of and in contact with the flanks of the conductive seed layer at the periphery of the opening.

According to an embodiment, the conductive seed layer comprises a first portion extending over all of the flanks of the insulating stack, the first portion of the conductive seed layer being in contact on the one hand with the insulating stack and on the other hand with the flanks of the conductive element.

According to an embodiment, the conductive seed layer comprises a second portion extending over the entire lower side of the opening, the second portion of the conductive seed layer being in contact on the one hand with the metal pad and on the other with the lower side of the conductive element.

According to an embodiment, the conductive seed layer comprises a third portion extending on the upper side of the insulating stack around the opening, the third portion of the conductive seed layer being in contact on the one hand with the upper side of the insulating stack and on the other hand with the lower side of an upper portion of the conductive element.

### BRIEF DESCRIPTION OF FIGURES

The foregoing features and advantages, as well as others, will be described in detail in the rest of the disclosure of specific embodiments given as an illustration and not limitation with reference to the accompanying drawings, in which:

FIG. 1 is a cross-section view, partial and simplified, of an example of an electronic device;

FIG. 2 is a cross-section view, partial and simplified, of an example of an electronic device according to a first embodiment;

FIGS. 3A,3B,3C,3D,3E, and 3F, are cross-section views, partial and simplified, of structures obtained from successive steps of an example of a method of manufacturing the electronic device illustrated in FIG. 2;

FIG. 4 is a cross-section view, partial and simplified, of an example of an electronic device according to a second embodiment; and

FIGS. 5A,5B and 5C, are cross-section views, partial and simplified, of structures obtained from successive steps of an example of a method of manufacturing the electronic device illustrated in FIG. 4.

### DETAILED DESCRIPTION

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and have been described in detail.

Unless otherwise specified, when reference is made to two elements being connected to each other, this means directly connected without any intermediate elements other than conductors, and when reference is made to two elements being coupled to each other, this means that these two elements may be connected or may be connected via one or more other elements.

In the following description, where reference is made to absolute position qualifiers, such as the terms "front", "back", "top", "bottom", "left", "right", etc., or relative position qualifiers, such as the terms "top", "bottom", "upper", "lower", etc., or orientation qualifiers, such as "horizontal", "vertical", etc., reference is made unless otherwise specified to the orientation of the drawings.

Unless specified otherwise, the expressions "about", "approximately", "substantially", and "in the order of" signify plus or minus 10% or 10°, preferably of plus or minus 5% or 5°.

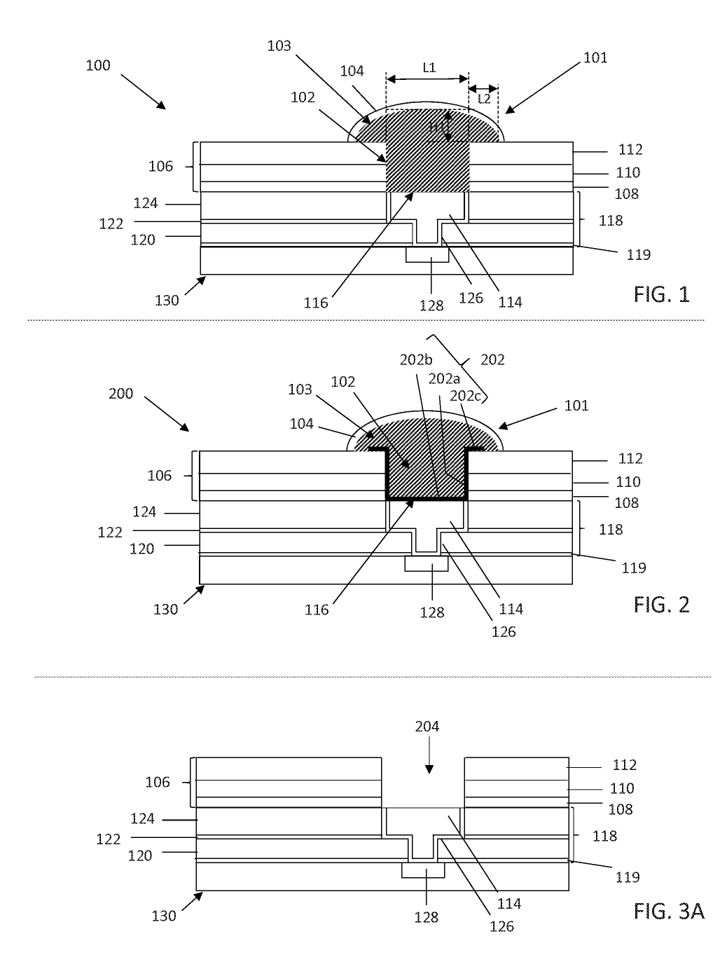

FIG. 1 is a cross-section view, partial and simplified, of an example of an electronic device 100.

Electronic device 100 comprises a conductive element 101. For example, conductive element 101 is an over-pad metallization or OPM.

Conductive element 101 comprises, for example, two portions, a lower portion 102 and an upper portion 103. The upper portion 103 of conductive element 101 is, for example, in contact, by its lower side, with the upper side of the lower portion 102 of conductive element 101. As an example, the two portions of conductive element 101 are round, square, or rectangular in top view.

Conductive element 101 and, more particularly, the lower and upper portions 102 and 103 of conductive element 101 are made of one and the same material. As an example, conductive element 101 is made of a metallic material, for example a material that can be deposited by an electroless deposition method. As an example, conductive element 101 is made of nickel. As a variant, conductive element 101 is made of gold, titanium, palladium, or a combination of a plurality of these materials, possibly in combination with nickel.

As an example, the lower portion 102 of conductive element 101 extends across a width L1, for example corresponding to the diameter of the lower portion 102 of conductive element 101 taken in the plane of its upper side. As an example, width L1 is in the range from 10 µm to 500 µm, and is for example in the order of 50 µm.

As an example, the upper portion 103 of conductive element 101 has a planar lower side. The upper portion 103 of conductive element 101 for example has a rounded upper side, for example the shape of an arc of a circle. As an example, the lower and upper sides of the upper part 103 of conductive element 101 meet on their peripheries.

As an example, the upper portion 103 of conductive element 101 extends along a height H1, from the upper side of the lower portion 102 of conductive element 101 to the upper end of the upper side of the upper portion 103 of the structure. Height H1 is, for example, in the range from 0.1 µm to 10 µm, for example in the order of 3 µm.

As an example, the upper portion 103 of conductive element 101 is centered on the lower portion 102 of conductive element 101. That is, the center of the upper portion 103 and the center of the lower portion 102 of conductive element 101 are aligned. As an example, the upper portion 103 of conductive element 101 extends over a surface area, taken on its lower side, greater than the surface area of the lower portion 102 of conductive element 101, taken on its upper side. In other words, the lower side of the upper portion 103 of conductive element 101 extends over the entire surface of the upper side of the lower portion 102 of conductive element 101 and beyond. Conductive element 101 thus has the shape of a mushroom having its stem corresponding to lower portion 102 and having its cap corresponding to upper portion 103.

As an example, the upper portion 103 of conductive element 101, more precisely the lower side of the upper portion 103 of conductive element 101, protrudes, for example over the entire periphery, from the lower portion 102 of conductive element 101 by a width L2. As an example, the upper portion 103 of conductive element 101 has a width, for example corresponding to the diameter of the lower side of the upper portion 103 of conductive element 101, equal to L1+2×L2.

As an example, width L2 is equal to height H1. As an example, width L2 is in the range from 0.1 µm to 10 µm, for example in the order of 3 µm.

Conductive element 101, in particular the upper portion 103 of conductive element 101, is covered by a conductive layer 104. The upper portion 103 of conductive element 101 is, for example, in contact, by its upper side, with the lower side of conductive layer 104. Layer 104 covers, for example, the entire surface area of the upper side of the upper portion 103 of conductive element 101. Layer 104 has, for example, a constant thickness, for example in the range from 100 nm to 500 nm, for example in the order of 350 nm.

As an example, layer 104 is made of a metallic material, for example a material that can be deposited by an electroless deposition method. As an example, layer 104 is made of palladium. As a variant, layer 104 is made of nickel, gold, titanium, or a combination of a plurality of these materials, possibly taken in combination with palladium.

As an example, conductive element 101 is intended to be connected to an external device via a wire soldered to the upper layer of layer 104.

Conductive element 101 extends inside and on top of an insulating stack 106, for example a stack of insulating layers. More particularly, the lower portion 102 of conductive element 101 is laterally surrounded by stack 106. As an example, the lower portion 102 of conductive element 101 is in contact, by its flanks, with the flanks of insulating stack 106. More precisely, the lower portion 102 of conductive element 101 has all of its flanks in contact with the flanks of insulating stack 106. As an example, the lower side of the upper portion 103 of conductive element 101 is also in contact with the upper side of insulating stack 106.

As an example, insulating stack 106 comprises, in the order, from the lower side of stack 106, an insulating layer 108, another insulating layer 110, and yet another insulating layer 112. As an example, the second insulating layer 110 is in contact, by its lower side, with insulating layer 108 and by its upper side, with insulating layer 112.

As an example, layer 108 is a nitride layer, for example a silicon nitride layer. As an example, layer 108 has a thickness in the range from 20 nm to 100 nm, for example in the order of 40 nm.

As an example, layer 110 is a layer of phosphorus glass or PSG (PhosphoSilicate Glass). As an example, layer 110 has a thickness in the range from 50 nm to 1 µm, for example in the order of 500 nm.

For example, layer 112 is a nitride layer, for example made of silicon nitride. As an example, layer 112 has a thickness in the range from 50 nm to 1 µm, for example in the order of 600 nm.

As an example, conductive element 101 extends through insulating stack 106 until it reaches a metal contact pad 114.

Conductive element 101 is, for example, in contact with an upper side 116 of metal pad 114.

For example, metal pad 114 is laterally surrounded by another insulating stack 118. As an example, the other insulating stack 118 comprises, in the order from the lower side of stack 118, an insulating layer 119, another insulating layer 120, another insulating layer 122, and another insulating layer 124. As an example, layer 124 is for example formed under and for example in contact with layer 108 of stack 106. As an example, insulating layer 122 is in contact, by its lower side, with insulating layer 120 and by its upper side, with insulating layer 124. As an example, insulating layer 120 is in contact, by its lower side, with insulating layer 119.

As an example, layer 119 is a nitride layer, for example made of silicon nitride.

As an example, layer 120 is a layer of undoped silicate glass or USG.

As an example, layer 122 is a nitride layer, for example made of silicon nitride.

As an example, layer 124 is a layer of undoped silicate glass or USG.

As an example, metal pad 114 does not have a constant width along stack 118. As an example, metal pad 114 is wider on the upper side of stack 118 than on the lower side of stack 118. As an example, metal pad 114 has a first width in layers 124 and 122 and a second width in layers 120 and 119.

Metal pad 114 is, for example, separated from the flanks of stack 118 by another conductive layer 126. As an example, conductive layer 126 is a layer of a metallic material, for example titanium, titanium nitride, tantalum, or tantalum nitride.

As an example, metal pad 114 extends through insulating stack 118 all the way to a conductive layer 128. Conductive layer 128 corresponds, for example, to a track or to a contact of an interconnection network 130.

The inventors have found that, in such a structure, when conductive element 101 is formed by an autocatalytic growth method, the latter poorly adheres to the surrounding insulating stack 106. Indeed, in an autocatalytic growth forming method, conductive element 101 grows from metal pad 114 only and not from stack 106. Conductive element 101 is thus not integral with stack 106. Mechanical problems caused by thermal expansion and contraction due to temperature variations can thus lead to openings or cracks between element 101 and stack 106, which can reach metal pad 114. Pad 114 is then exposed to an external environment, which can lead to its degradation. The lifetime of the devices is thereby decreased.

FIG. 2 is a cross-section view, partial and simplified, of an example of an electronic device 200 according to a first embodiment.

Device 200 is similar to the device 100 shown in FIG. 1, with the difference that device 200 comprises, between the flanks of conductive element 101 and the flanks of stack 106, a conductive seed layer 202.

As an example, conductive layer 202 comprises a first portion 202a between the flanks of conductive element 101 and the flanks of stack 106. As an example, the flanks of the lower portion 102 of conductive element 101 are fully covered by conductive layer 202. As an example, at the interface between the flanks of stack 106 and conductive element 101, layer 202 is in contact, on the one hand, with conductive element 101 and, on the other hand, with the sides of stack 106. Portion 202a of layer 202 advantageously enables to ensure an adhesion of conductive element 101 to the flanks of stack 106.

In addition, layer 202 comprises a second portion 202b between the lower side of conductive element 101 and the upper side 116 of metal pad 114. As an example, at the interface between conductive element 101 and metal pad 114, layer 202 is in contact, on the one hand, with conductive element 101 and in contact, on the other hand, with metal pad 114. Portion 202b of layer 202 advantageously enables to ensure an electrical connection between metal pad 114 and conductive element 101.

Further, conductive layer 202 comprises a third portion 202c between the lower side of the upper portion of conductive element 101 and the upper side of stack 106. As an example, at the interface between the upper side of stack 106 and conductive element 101, layer 202 is in contact with the upper side of stack 106 and in contact with the lower side of the upper portion 103 of conductive element 101. As an example, layer 202 does not extend under the entire lower side of the upper portion 103 of conductive element 101. Portion 202c of layer 202 advantageously enables to ensure an adhesion of conductive element 101 to the top of the flanks of stack 106 and to the upper side of stack 106.

As an example, layer 202 is continuous and comprises no opening. In other words, layer 202 entirely covers the lower side and the flanks of conductive element 101. As an example, conductive element 101 covers the entire upper side of layer 202.

Layer 202 is for example made of a metallic material.

According to an embodiment, layer 202 is made of a material that can be deposited by a vapor deposition method. Layer 202 is for example made of a material capable of being deposited by a chemical vapor deposition or CVD method or a physical vapor deposition or PVD method.

AS a variant, layer 202 is deposited by evaporation.

As an example, layer 202 is made of nickel, titanium, titanium nitride, tantalum, tantalum nitride, titanium-copper, or a combination of a plurality of these materials.

Layer 202 for example has a constant thickness. As an example, layer 202 for example has a thickness in the range from 50 nm to 500 nm, for example in the order of 200 nm.

As an example, the width L1 of the lower portion 102 of conductive element 101 is less than the width of pad 114. As an example, the sum of the width of the lower portion 102 of conductive element 101 and twice the width of the portion 202a of layer 202 is less than the width of pad 114.

An advantage of the present embodiment is that layer 202 enables to reinforce the cohesion of conductive element 101 on the flanks of stack 106. This increased cohesion with layer 202 enables to limit the risk of creation of cracks at the interface between conductive element 101 and stack 106.

An advantage of the present embodiment is that it enables to decrease the risk of corrosion of the metal pad 114 due to moisture, debris, and contaminants present in the external environment. By decreasing the risk of corrosion of metal pad 114, the lifetime of the devices can be extended, and the likelihood of faulty devices being manufactured is decreased.

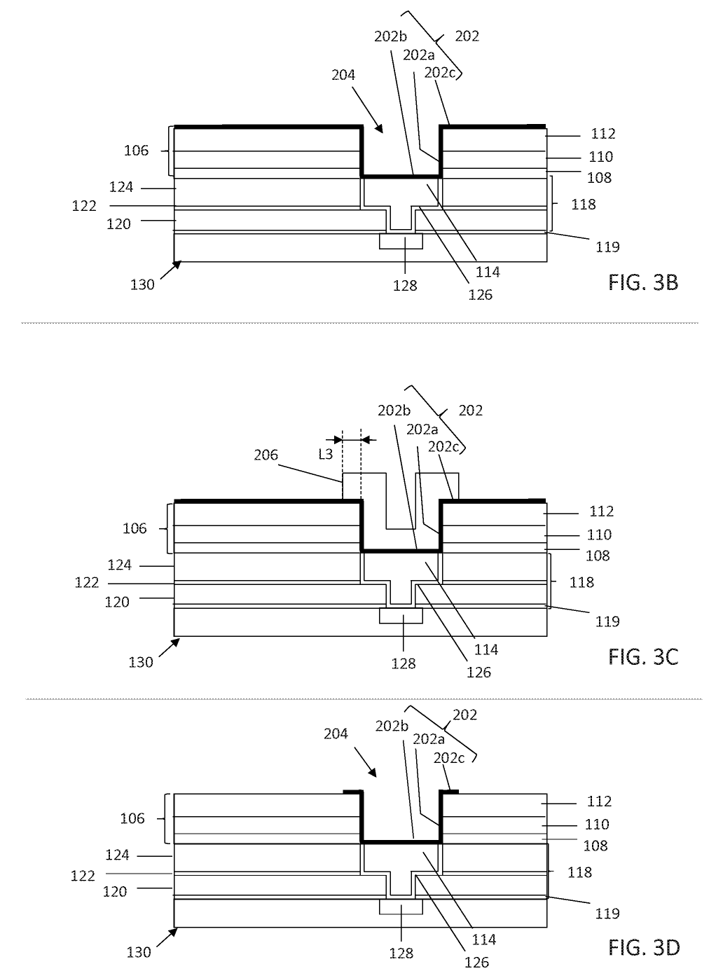

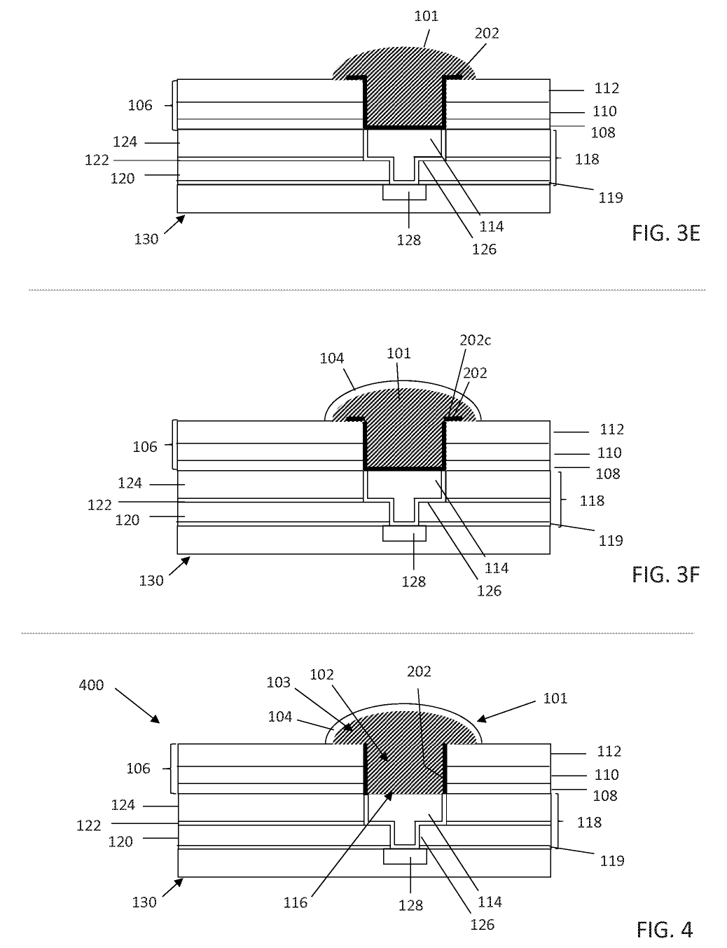

FIGS. 3A,3B,3C,3D,3E,3F, are cross-section views, partial and simplified, of structures obtained from successive steps of an example of a method of manufacturing the electronic device 200 illustrated in FIG. 2.

FIG. 3A is a structure comprising stacks 106 and 118 formed on interconnection stack 130. The structure shown in FIG. 3A further comprises metal pad 114. In addition, the structure shown in FIG. 3A comprises layer 126 at the interface between metal pad 114 and the flanks of stack 118.

As an example, the structure shown in FIG. 3A comprises, in stack 106, an opening 204. Opening 204 is formed, for example, opposite metal pad 114. Opening 204 extends, for example, all the way to the upper side 116 of metal pad 114, exposing surface 116.

FIG. 3B illustrates a structure obtained at the end of a step of deposition of layer 202 on the upper side of the structure shown in FIG. 3A.

As an example, during this step, layer 202 is deposited by a chemical vapor deposition method. As an example, layer 202 is deposited by a chemical vapor deposition method. As a variant, layer 202 is deposited by a physical vapor deposition method.

As an example, layer 202 is deposited over the entire upper side of the structure shown in FIG. 3A. As an example, layer 202 is deposited in contact with the upper side of the structure illustrated in FIG. 3A. More specifically, layer 202 is deposited in contact with the entire upper side of stack 106. Further, layer 202 is deposited in opening 204, in contact with the upper side of metal pad 114 and in contact with the flanks of stack 106.

As an example, layer 202 is deposited continuously. Layer 202 is for example deposited with a constant thickness along its entire length.

As an example, the step of deposition of layer 202 is preceded by a step of surface treatment on the upper side of the structure illustrated in FIG. 3A. As an example, the treatment step comprises exposing the surface of the structure to a plasma, for example an argon plasma.

FIG. 3C illustrates a structure obtained at the end of a step of deposition of a masking layer 206 on the upper side of the structure shown in FIG. 3B.

During this step, masking layer 206 is deposited, for example, all over the wafer, so as to cover the entire upper side of layer 202.

Masking layer 206 is for example deposited in contact with layer 202.

Masking layer 206 is, for example, a layer made of a resin, for example of resist.

At the end of the step of deposition of masking layer 206, the latter is for example exposed to ultraviolet radiation and then developed so as to only be deposited locally and removed everywhere else. As an example, masking layer 206 is, at the end of this step, kept opposite opening 204 and around opening 204. As an example, masking layer 206 is further kept around opening 204 across a width L3 in the range from 100 nm to 10 µm, for example in the order of 1 µm.

FIG. 3D illustrates a structure obtained at the end of a step of etching of layer 202 through the masking layer 206 of the structure shown in FIG. 3C.

As an example, in this step, layer 202 is etched by using masking layer 206 as an etch mask, so as to expose, outside of the location opposite masking layer 206, the upper surface of stack 106.

As an example, at the end of this step, layer 202 only remains in front of masking layer 206.

As an example, at the end of this step, masking layer 206 is for example removed to expose the upper surface of layer 202.

At the end of the removal of masking layer 206, layer 202 remains in opening 204, on top of and in contact with the upper side of metal pad 114, forming portion 202b of layer 202. Further, at the end of the removal of masking layer 206, layer 202 remains on top of and in contact with the flanks of stack 106, forming portion 202a of layer 202. Further, at the end of the removal of masking layer 206, layer 202 remains on the upper side of the stack, forming portion 202c of layer 202.

FIG. 3E illustrates a structure obtained at the end of a step of forming of conductive element 101 on the upper side of layer 202 of the structure illustrated in FIG. 3D.

As an example, during this step, conductive element 101 is formed in one and the same step. As an example, during this step, conductive element 101 is formed by an electroless deposition method. As an example, conductive element 101 is formed from layer 202, on top of and in contact with layer 202.

During this step, element 101 thus grows simultaneously from the portions 202a, 202b, and 202c of layer 202. Element 101 further grows from the flanks of layer 202 formed on the upper side of layer 112. Thus, at the end of this step, element 101 covers the flanks of layer 202 outside opening 204, on the upper side of layer 112.

FIG. 3F illustrates a structure obtained at the end of a step of forming of layer 104 on the upper side of the conductive element 101 of the structure illustrated in FIG. 3E.

As an example, during this step, layer 104 is formed in one and the same step. As an example, during this step, layer 104 is formed by an electroless deposition method. As an example, layer 104 is formed from conductive element 101, on top of and in contact with conductive element 101.

FIG. 4 is a cross-section view, partial and simplified, of an example of an electronic device 400 according to a second embodiment.

Device 400 is similar to the device 200 shown in FIG. 2, with the difference that in device 400, seed layer 202 incudes only the first portion 202a between the flanks of conductive element 101 and the flanks of stack 106.

In this embodiment, portion 202b is omitted. As an example, the conductive element 101 is in contact, by its lower side, with the upper side of the metal pad 114.

In this embodiment, portion 202c is omitted. As an example, the lower side of the upper portion of conductive element 101 is in contact with the upper side of stack 106.

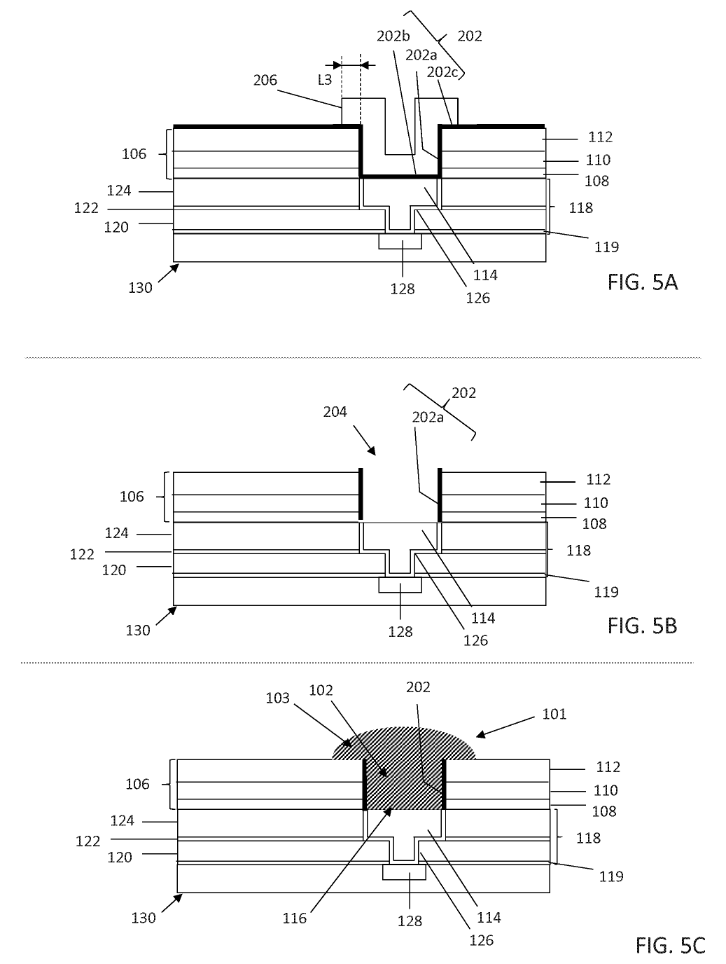

FIGS. 5A,5B and 5C are cross-section views, partial and simplified, of structures obtained from successive steps of an example of a method of manufacturing the electronic device 400 illustrated in FIG. 4.

FIG. 5A corresponds to FIG. 3B, the start of the method of manufacturing the device 400 being identical the start of the method of manufacturing the device 200 described in relation with FIGS. 3A and 3B.

FIG. 5B illustrates a structure obtained at the end of a step of etching of layer 202 of the structure shown in FIG. 5A.

Contrary to what was described in the method of manufacturing the device 200, the method of manufacturing the device 400 involves, during this step, the etching layer 202 without using the masking layer 206.

For example, the etch used here is an anisotropic etch, for example a dry etch. For example, the etch selectivity removes layer 202 but leaves the layers in the stack 106 intact.

As an example, at the end of this step, layer 202 only remains, in opening 204, in the lateral flanks of the stack 106 forming portion 202a of layer 202.

FIG. 5C illustrates a structure obtained at the end of a step of forming of conductive element 101 on the upper side of layer 202 of the structure illustrated in FIG. 5B.

This step is similar to the one described in relation with FIG. 3E, with the difference that element 101 grows only from the portion 202a of layer 202. Element 101 further grows from the upper side of layer 202 which are flush with the upper side of layer 112. Thus, at the end of this step, element 101 covers the upper side of layer 202 that lead to the upper side of the stack 106.

Following this step, in order to obtain the device 400, layer 104 may be formed in a manner similar to that described in relation to FIG. 3F.

Various embodiments and variants have been described. The person skilled in the art will understand that certain features of these various embodiments and variants could be combined, and other variants will become apparent to the person skilled in the art.

Finally, the practical implementation of the described embodiments and variants is within the reach of the person skilled in the art on the basis of the functional indications given above.

1. A method of manufacturing an electronic device comprising the following successive steps:
a) forming a structure comprising a metal pad coated with an insulating stack, the insulating stack comprising an opening facing the metal pad;
b) depositing a conductive seed layer in the opening on top of and in contact with an upper side of the metal pad, the conductive seed layer further extending on top of and in contact with flanks of the insulating stack and on top of and in contact with an upper side of the insulating stack at a periphery of the opening;
c) removing a part of the conductive seed layer by etching while preserving the conductive seed layer at least on the flanks of the insulating stack in the opening ; and
d) forming, by an electroless deposition method, a conductive element on top of and in contact with an entire upper side of the conductive seed layer, the conductive element extending on and in contact with the upper side of the insulating stack outside of the opening.

2. The method according to claim 1, wherein the conductive element is made of nickel.

3. The method according to claim 1, wherein the conductive seed layer is made of nickel, titanium, titanium nitride, tantalum, tantalum nitride, or an alloy of titanium and copper.

4. The method according to claim 1, wherein, during step b), the conductive seed layer is deposited with a thickness in a range from 50 nanometers (nm) to 500 nm.

5. The method according to claim 1, wherein, during step b), the seed conductive layer is deposited by a vapor deposition method or a physical vapor deposition method.

6. The method according to claim 5, wherein, during step b), the seed conductive layer is deposited by a chemical vapor deposition method.

7. The method according to claim 1, comprising, between steps a) and b), performing plasma treatment of a surface of the metal pad.

8. The method according to claim 1, comprising, after step c), depositing another conductive layer on top of and in contact with an upper side of the conductive element.

9. The method according to claim 8, wherein the other conductive layer is made of palladium.

10. The method according to claim 1, wherein during step c), the conductive seed layer is further preserved on the lower side of the opening and on the upper side of the insulating stack around the opening.

11. An electronic device comprising:
a metal pad coated by an insulating stack, the insulating stack comprising an opening facing the metal pad;
a conductive seed layer in the opening on top of and in contact with an upper side of the metal pad, the conductive seed layer further extending at least on top of and in contact with flanks of the insulating stack in the opening; and
a conductive element on top of and in contact with the conductive seed layer, the conductive element extending into the opening and extending on and in contact with the upper side of the insulating stack outside of the opening.

12. The device according to claim 11, wherein the conductive seed layer comprises a first portion extending over all of the flanks of the insulating stack, the first portion of the conductive seed layer being in contact with the insulating stack and with the flanks of the conductive element.

13. The device according to claim 12, wherein the conductive element is on top and in contact with the upper side of the conductive seed layer that lead to the upper side of the stack 106.

14. The device according to claim 11, wherein the conductive seed layer comprises a second portion extending over an entire lower side of the opening, the second portion of the conductive seed layer being in contact with the metal pad and with the lower side of the conductive element.

15. The device according to claim 11, wherein the conductive seed layer comprises a third portion extending over the upper side of the insulating stack around the opening, the third portion of the conductive seed layer being in contact with the upper side of the insulating stack and with the lower side of an upper portion of the conductive element, and wherein the conductive element is in contact with the flanks of the third portion of the conductive seed layer, on the upper side of the insulating stack.
